(19) United States
(12) Patent Application Publication
(10) Pub. No.: US 2007/0246805 A1
(43) Pub. Date: Oct. 25, 2007

(54) MULTI-DIE INDUCTOR

(76) Inventors: Ligang Zhang, Oceanside, CA (US); John M. Czarnowski, Austin, TX (US)

Correspondence Address: ZAGORIN O'BRIEN GRAHAM LLP, 7600B NORTH CAPITAL OF TEXAS HIGHWAY, SUITE 350, AUSTIN, TX, 78731, US

(21) Appl. No.: 11/427,595

(22) Filed: Jun. 29, 2006

Related U.S. Application Data
(60) Provisional application No. 60/745,585, filed on Apr. 25, 2006.

(51) Int. Cl. H01L 23/552

(52) U.S. Cl. 257/659

(57) ABSTRACT

A technique for improving the quality factor of an inductor includes increasing a cross-sectional area of the inductor by increasing a vertical dimension associated with the inductor. An apparatus includes an inductor formed partially in a first integrated circuit die and formed partially in at least a second integrated circuit die. The inductor may be formed partially in at least one interconnect structure between the first integrated circuit die and the second integrated circuit die. In at least one embodiment of the invention, the inductor is self-shielding and is configured to generate a magnetic field in response to a current flowing through coupled conductor portions of the self-shielding inductor. The magnetic field of the self-shielding inductor is substantially confined to a core region of the self-shielding inductor.

### CROSS-REFERENCE TO RELATED APPLICATION(S)

This application claims the benefit under 35 U.S.C. §119(e) of U.S. Provisional Application No. 60/745,585, filed Apr. 25, 2006, entitled “MULTI-DIE INDUCTOR” by Ligang Zhang and John M. Czarnowski, which application is hereby incorporated by reference.

### BACKGROUND

1. Field of the Invention

The present invention relates to integrated circuits, and more particularly to such integrated circuits incorporating inductor structures.

2. Description of the Related Art

Many modern integrated circuit devices, e.g., stable oscillators, require a high-Q (i.e., quality factor) inductor that is immune to external noise sources to achieve desired specifications. Crystal oscillators may be employed, but typically require an off-chip crystal mounted elsewhere on a printed-wiring-board. LC oscillators offer the potential advantage of being able to incorporate such an oscillator on-chip.

To achieve a suitable oscillator for certain applications (e.g, inclusion in a narrow bandwidth phase-locked loop (PLL)), a high-Q (i.e., quality factor) LC oscillator is typically required. For example, a Q>20 may be required for certain applications. It is difficult to achieve such a high-Q with conventional on-chip inductors using conductor and dielectric layer compositions and thicknesses which are typically encountered in traditional integrated circuit processes. In addition, such inductors are susceptible to electromagnetic interference from external sources of noise. For certain applications using LC oscillators, a low bandwidth PLL is desirable to ensure that jitter from a noisy source is not passed to the output. In contrast, high bandwidth PLLs tend to pass input jitter to the output. However, the ability of a PLL to resist the pulling from external noise sources is directly proportional to the loop bandwidth. Inductors inside of the PLL, particularly inside an LC oscillator included in the PLL, are most prone to pulling. Accordingly, it is desirable to shield the inductor from external noise sources, particularly in low bandwidth applications to reduce the possible degradation in performance. Therefore, improvements to high-Q LC oscillators are desired to achieve stable oscillators, particularly for use as low-jitter clock sources.

### SUMMARY

A technique for improving the quality factor of an inductor includes increasing a cross-sectional area of the inductor by increasing a vertical dimension associated with the inductor. In at least one embodiment of the invention, an apparatus includes an inductor formed partially in a first integrated circuit die and formed partially in at least a second integrated circuit die. The inductor may be formed partially in at least one interconnect structure between the first integrated circuit die and the second integrated circuit die. In at least one embodiment of the invention, the inductor is self-shielding and is configured to generate a magnetic field in response to a current flowing through coupled conductor portions of the self-shielding inductor. The magnetic field of the self-shielding inductor is substantially confined to a core region of the self-shielding inductor.

In at least one embodiment of the invention, a method of manufacturing includes interconnecting a first integrated circuit die and at least a second integrated circuit die to form an inductor. The first integrated circuit die includes first conductor portions of the inductor and the second integrated circuit die includes second conductor portions of the inductor. In at least one embodiment of the invention, the inductor is self-shielding and is configured to generate a magnetic field in response to a current flowing through coupled conductor portions. The magnetic field of the self-shielding inductor is substantially confined to a core region of the self-shielding inductor.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a schematic/block diagram of an exemplary LC oscillator circuit consistent with at least one embodiment of the present invention.

FIG. 2 illustrates a perspective view of a helical coil

FIG. 3 illustrates a portion of an ideal, multi-turn solenoid.

FIG. 4 illustrates magnetic field lines associated with a finite-length, multi-turn solenoid.

FIG. 5 illustrates a graphical representation of inductance and inductor Q as a function of inductor length for an approximately single turn, solenoidal inductor.

FIG. 6 illustrates a perspective view of an ideal, multi-turn toroid.

FIG. 7 illustrates a cross sectional view of an ideal toroid, the cross sectional plane being orthogonal to an axis of the ideal toroid.

FIG. 8A illustrates a top-down, two-dimensional view of a twenty turn, self-shielding inductor consistent with at least one embodiment of the present invention.

FIG. 8B illustrates a top-down view of via structures of a sidewall of the inductor of FIG. 8A consistent with at least one embodiment of the present invention.

FIG. 8C illustrates a top-down view of via structures of a sidewall of the inductor of FIG. 8A consistent with at least one embodiment of the present invention.

FIG. 9 illustrates a top-down, perspective view of an eight turn, self-shielding inductor consistent with at least one embodiment of the present invention.

FIG. 10 illustrates a top-down, perspective view of a four turn, self-shielding inductor consistent with at least one embodiment of the present invention.

FIG. 11A illustrates a bottom-up, perspective view of a fractional-turn, self-shielding inductor consistent with at least one embodiment of the present invention.

FIG. 11B illustrates a top-down view of an exemplary conductor portion consistent with at least one embodiment of the present invention.

FIG. 12 illustrates a cross-sectional, perspective view of a fractional-turn, self-shielding inductor consistent with at least one embodiment of the present invention, the cross sectional plane being parallel to an axis of the self-shielding inductor.

FIG. 13A illustrates a cross-sectional, perspective view of a fractional-turn, self-shielding inductor consistent with at least one embodiment of the present invention, the cross sectional plane being parallel to an axis of the self-shielding inductor.

FIG. 13B illustrates a bottom-up, perspective view of a fractional-turn, self-shielding inductor consistent with at least one embodiment of the present invention.

FIG. 13C illustrates a cross-sectional view of a fractional-turn, self-shielding inductor consistent with at least one embodiment of the present invention.

FIG. 14 illustrates a cross-sectional view of a portion of a fractional-turn, self-shielding inductor consistent with at least one embodiment of the present invention, the cross sectional plane being parallel to an axis of the self-shielding inductor.

FIG. 15 illustrates a top-down view of a capacitor structure consistent with at least one embodiment of the invention.

FIG. 16 illustrates a cross-sectional, perspective view of a fractional-turn, self-shielding inductor including at least one through-substrate structure consistent with at least one embodiment of the present invention, the cross sectional plane being parallel to an axis of the self-shielding inductor.

FIG. 17A illustrates a cross-sectional, perspective view of a fractional-turn, self-shielding inductor including at least one through-substrate structure consistent with at least one embodiment of the present invention, the cross sectional plane being parallel to an axis of the self-shielding inductor.

FIG. 17B illustrates a cross-sectional, perspective view of an inductor formed by at least two interconnected integrated circuit die consistent with at least one embodiment of the invention.

FIGS. 18A and 18B illustrate cross-sectional views of an inductor being formed by a technique for coupling two integrated circuit die consistent with at least one embodiment of the invention.

FIG. 18C illustrates a top-down view of the two integrated circuit die of FIG. 18A and 18B consistent with at least one embodiment of the invention.

FIGS. 19A and 19B illustrate cross-sectional views of an inductor being formed by a technique for coupling two integrated circuit die consistent with at least one embodiment of the invention.

FIGS. 20A-D illustrate cross-sectional views of an inductor being formed by a technique for coupling two integrated circuit die consistent with at least one embodiment of the invention.

FIGS. 21A-C illustrates cross-sectional views of an inductor being formed by an exemplary technique for stacking integrated circuit die.

FIG. 22 illustrates a cross-sectional view of an inductor formed by a plurality of integrated circuit die in a pyramid stack configuration consistent with at least one embodiment of the invention.

FIG. 23 illustrates a cross-sectional view of an inductor formed by a plurality of integrated circuit die in a same-die stack configuration consistent with at least one embodiment of the invention.

FIG. 24 illustrates a cross-sectional view of an inductor formed by a plurality of integrated circuit die in an overhang cross stack configuration consistent with at least one embodiment of the invention.

The use of the same reference symbols in different drawings indicates similar or identical items.

### DESCRIPTION OF THE PREFERRED EMBODIMENT(S)

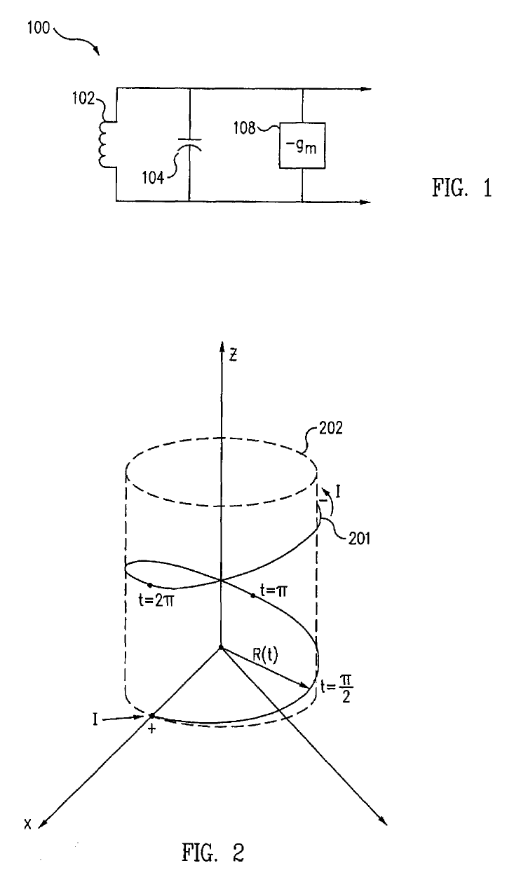

Referring to FIG. 1, an integrated circuit die includes an LC oscillator circuit e.g., circuit 100, including inductor 102, capacitor 104, and gain stage 108. The quality factor associated with the resonant circuit (i.e., Q_{RESONANT}) describes the ability of the circuit to produce a large output at a resonant frequency and also describes the selectivity of the circuit. The Q_{RESONANT} may be substantially affected by the quality factor of an inductor (i.e., Q_{L}) included in the resonant circuit. In general, Q_{L} for an inductor modeled as an inductance in series with a resistance is

$${Q}_{L} = \frac{ω L}{R}$$

where ω is the angular frequency of oscillation, L is the inductance of the inductor, and R is the effective series resistance of the inductor.

In general, an inductor includes an input, an output, and a coil disposed therebetween through which current rotates. The coil introduces inductance into an electrical circuit, to produce magnetic flux. As referred to herein, a coil is a conductor having at least a fractional number of turns around a core region of space. An individual turn of an exemplary coil may be defined by a curve traced by the tip of a position vector, e.g, R(t)=x(t)i+y(t)j+z(t)k from t=a to t=b. As referred to herein, one full turn of the coil is defined by a portion of the curve as t runs from 0 to 2π. However, an exemplary coil may make any number of full turns or fractional turns. For example, less than one full turn, i.e., R(t) for 0<t<2π, may form the coil. Small inductors with a good quality factor (Q) have been very difficult to design given modern integrated circuit design restrictions. Traditionally, inductors are designed to be metal traces forming planar loops (e.g., spiral inductors). One limitation on this type of inductor is that as the inductance value L decreases, its quality factor Q_{L} tends to get smaller as well. This makes small inductors less useful in high-frequency, low-loss VCO designs.

Referring to FIG. 2, individual turns of a coil (e.g., coil 201) included in an inductor may be defined by the curve of a helix, i.e., R(t)=(cos t)i+(sin t)j+tk, formed around cylindrical core region (e.g., core region 202). The pitch of a helical coil is the length of one full helix turn, measured along the helix axis (e.g., the z-axis of coil 201). The coil may be right-handed (i.e., for a vertical coil, front strands of the coil move from the lower left to the upper right) or left-handed (i.e., for a vertical coil, front strands of the coil move from the lower right to the upper left). A coil formed in an integrated circuit manufacturing process may approximate an ideal helical coil by forming a polygonal-shaped core region (e.g., rectangular, square, octagonal, or other suitable shape) rather than a cylindrical-shaped core region. The axis of the helical coil is parallel to the front surface of an integrated circuit.

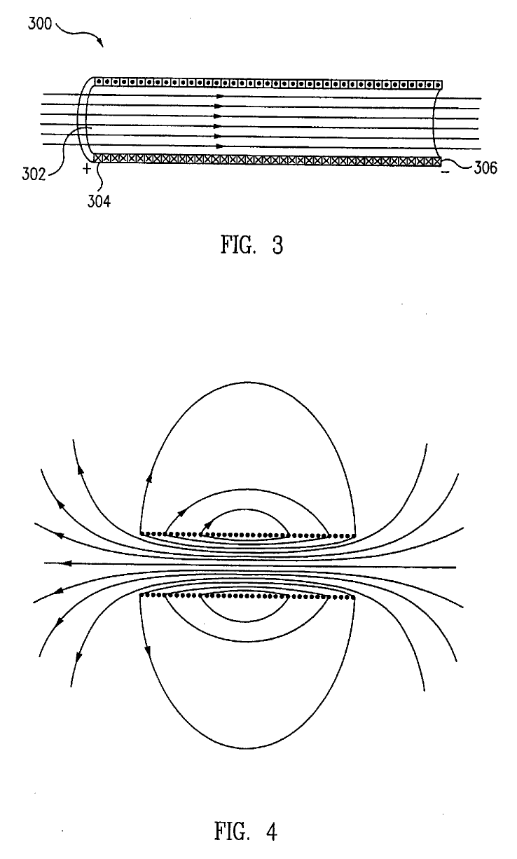

An ideal inductor may be a solenoid, i.e., a low pitch helical coil that has a length much greater than the diameter of the coil. The pitch of the helical coil is small enough that the solenoid is effectively a cylindrical current sheet. Magnetic fields established by current flowing through the individual turns radiate in concentric circles from the turns and cancel such that the magnetic field inside the solenoid (i.e., in the core of the coil) at points far enough from the wires are effectively parallel to the helical axis. For an infinitely long solenoid, the magnetic field outside the solenoid approaches zero. Referring to ideal solenoid portion 300 of FIG. 3, when a current flows from positive node 304 to negative node 306, the current rotates through the solenoid (i.e., the current flows into the turns on the lower portion of the solenoid and the current flows out of the upper portion of the solenoid) and a magnetic field is generated within core region 302. However, a solenoid of finite length will establish a magnetic field at points external to the core of the solenoid (FIG. 4). Such a magnetic field is less confined and more susceptible to electromagnetic interference, which may change the effective inductance of the inductor.

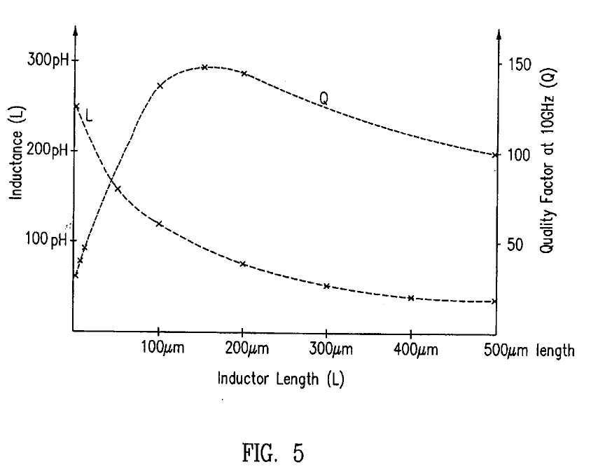

In an exemplary finite length solenoidal inductor (i.e., a coil formed around a polygonal-shaped core region to satisfy certain integrated circuit and semiconductor processing requirements rather than a cylindrical-shaped core region of an ideal solenoid) the coil turns are spaced close enough together so that leakage of magnetic flux from those gaps is negligible. However, because the coil is finite in length, the coil will have an external magnetic field that results in mutual inductance between the coil and external electromagnetic interference, which changes the realized inductance of a solenoidal inductor and degrades the quality of the solenoidal inductor. A cross-section of a core of an exemplary solenoidal inductor has a height of 200μ and a width of 200μ. Simulations of such a coil in a vacuum indicate that as the coil length increases (i.e., the length of the polygonal-shaped core region increases), the inductance decreases, but the associated Q_{L} at 10 GHz is maintained at high levels (i.e., greater than 100) for lengths greater than 100 μm (FIG. 5). These results are approximately the same for a coil substantially surrounded by silicon dioxide, air, or other non-conducting dielectric material.

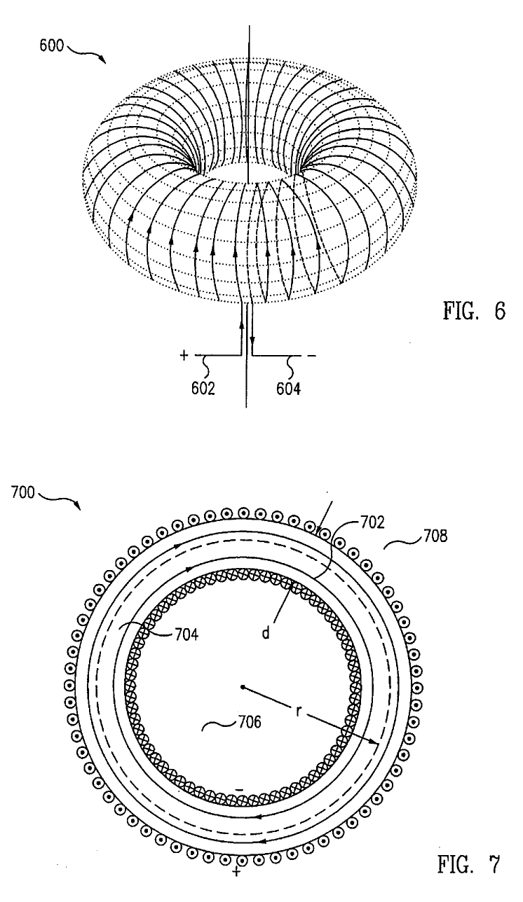

A technique for reducing the external magnetic field that results in mutual inductance between the solenoidal inductor and external electromagnetic interference, confines the magnetic field generated by the solenoidal inductor by self-enclosing the solenoidal inductor to form a toroidal inductor. Referring to FIG. 6, an ideal toroidal surface has an annular shape, which may be generated by revolving a circle around an axis external to the circle. As referred to herein, an ideal toroidal inductor is a finite length solenoid formed substantially symmetrically around an axis external to the solenoid and orthogonal to cross-sections of the solenoid coil to close itself (e.g., the input terminal 602 and output terminal 604 of inductor 600 are substantially adjacent coil portions). Referring to FIG. 7, the magnetic field inside the coil of a toroidal inductor (i.e., the magnetic field in the core region of the toroidal inductor) follows concentric circles of a particular magnetic field (e.g., magnetic field line 702 in core region 704 of inductor 700). The magnetic field is effectively zero at points outside the coil of the toroidal inductor (i.e., in center region 706 and region 708).

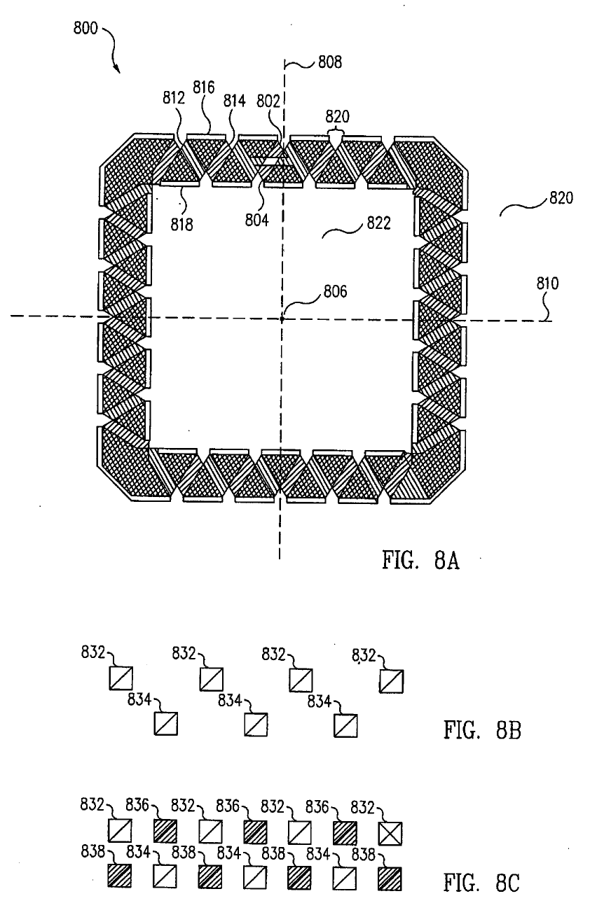

Referring to FIG. 8A, actual toroidal inductors (e.g., inductor 800) may be realized in an exemplary integrated circuit manufacturing technology by approximating an ideal toroidal inductor by forming a coil around an axis (e.g., the axis orthogonal to the page and intersecting center point 806) symmetrically in at least two dimensions. For example, a coil may be formed in a polygonal shape (e.g., rectangular, square, octagonal, or other suitable shape) around an axis orthogonal to a surface of an integrated circuit. The coil approximates an ideal helical coil by having a polygonal cross-section (e.g., rectangular, square, octagonal, or other suitably shaped cross-section), rather than a circular cross-section. Inductor 800 is symmetric about plane 808 and plane 810, i.e., magnetic fields external to inductor 800 (i.e., magnetic fields in center region 822 and region 820) and generated by current through inductor 800 (e.g., a current flowing into positive terminal 802 and out of negative terminal 804, the current flow being counter-clockwise around the axis orthogonal to the page and intersecting center point 806) have substantially equal and opposite components. Respective equal and opposite components effectively cancel magnetic fields generated external to the coil by such components.

In a particular application, a typical inductor may be shielded to achieve satisfactory performance at high frequencies. At high frequencies, a non-ideal toroidal inductor (e.g., a toroidal inductor forming a rectangle centered about an axis and formed from a helical coil having angular turns) may be satisfactory for the particular application because conductor portions forming the coil are thicker than the skin depth of the material for particular frequencies, thereby substantially reducing penetration of electromagnetic interference having the particular frequencies into the core of the inductor coil. Low frequency electromagnetic interference generated by a distant source may penetrate the conductor portions forming the coil, which are thin with respect to the frequency of the electromagnetic interference (i.e., thinner than the skin depth of the material for the frequency of the electromagnetic interference). However, the effect on the magnetic field may be insubstantial because equal and opposite magnetic fields are induced by the electromagnetic interference due to symmetry introduced by the shape of the inductor.

The pitch of the coil forming inductor 800 may be limited by a particular integrated circuit manufacturing technology and may vary according thereto. Similarly, the space in between turns of inductor 800 (e.g., space 820) may vary according to the particular integrated circuit manufacturing technology. In general, decreases in space between the turns of inductor 800 reduce leakage of magnetic flux from the core of inductor 800, thereby reducing susceptibility of inductor 800 to external electromagnetic interference.

Individual turns of the coil forming inductor 800 include a top turn portion (e.g., top turn portion 812), a bottom turn portion (e.g., bottom turn portion 814), and sidewall turn portions (e.g., sidewall turn portions 816 and 818) coupling the top surface to the bottom surface. In at least one embodiment of the invention, inductor 800 is formed entirely in traditional integrated circuit layers, i.e., conductor and dielectric layer compositions having thicknesses which are typically encountered in traditional integrated circuit processes. For example, top turn portion 812 may be formed in the one or more top metal layers (e.g., metal-9) and bottom turn portion 814 may be formed in the one or more lowest metal layers (e.g., metal-1). The top and bottom turn portions may be patterned into solid conductor portions, if allowed by the particular integrated circuit manufacturing technology, or may be multiple metal lines coupled together to approximate solid conductor portions. Sidewall turn portions may be approximated by a plurality of conductive via structures formed in additional metal layers (e.g., metal-2-metal-8). In a typical integrated circuit process, metal layers are electrically coupled to adjacent metal layers (e.g., metal-2 is coupled to metal-3) by vias in a dielectric layer between the metal layers. Those vias are filled with conductive material.

Preferably, the vias are continuous, solid walls, but, discrete vias may be spaced a minimum distance apart and placed to form sidewalls of the coil. In an exemplary embodiment, additional rows of vias (e.g., vias 832 of FIG. 8B) are staggered from the first rows of vias (e.g., vias 834 of FIG. 8B) and are placed around the first set of vias, but in the same layer of vias to reduce the effective size of apertures formed between adjacent vias and to further attenuate any electromagnetic radiation of particular frequencies entering or leaving the core of the coil forming inductor 800. The vias in the typical integrated circuit process may be stacked on top of each other. However, vias in the typical integrated circuit layers may be formed without stacking adjacent vias, by staggering vias of adjacent layers from a location that would stack the vias. For example, vias formed in metal-2 (e.g., vias 836 and 838 of FIG. 8C) overlap the gaps formed by vias in metal-1 (e.g., vias 832 and 834 of FIG. 8C). Vias formed in alternating layers may be aligned, e.g., vias formed in metal-1 are aligned with vias formed in metal-3, and vias formed in metal-2 are aligned with vias formed in metal-4.

In at least one embodiment of the invention, the phase noise associated with a resonant circuit may be expressed as being proportional to the inductance of the resonant circuit:

$$PN ∝ \frac{L}{{Q}_{RESONANT}} .$$

The phase noise associated with a resonant circuit may also be expressed as being inversely proportional to the capacitance of the resonant circuit:

$$PN ∝ \frac{1}{{CQ}_{RESONANT}} .$$

To achieve a particular oscillating frequency, one technique for reducing the phase noise is to reduce L/Q_{L}. The power consumed by an exemplary resonant circuit is inversely proportional to the inductance and Q_{RESONANT}:

$$P ∝ \frac{1}{{LQ}_{RESONANT}} ,$$

In applications where Q_{RESONANT} is predominately affected by Q_{L}, Q_{RESONANT} is effectively Q_{L}:

$$PN ∝ \frac{L}{{Q}_{L}} and$$

$$P ∝ \frac{1}{{LQ}_{L}} .$$

Thus, a power constraint associated with a particular design may be satisfied while reducing phase noise by keeping the product of L and Q_{L} approximately constant while reducing L/Q_{L}.

One technique for reducing the inductance of the toroidal inductor is to reduce the cross-section of the core region of the coil. As the inductor cross-sectional area decreases by a factor of n, the resistance of the inductor decreases, but by a factor less than n, e.g., a reduction in the cross-sectional area by a factor of two may be matched by reductions in resistance of the coil by √2 and Q_{L} of the inductor is reduced by √2. A reduction in inductor Q_{L} increases phase noise of the resonant circuit because phase noise is inversely proportional to the Q_{L} of the inductor. Techniques for reducing the inductance while maintaining the Q_{L} associated with the inductor may provide an improved phase noise performance of the resonant circuit, which may be accomplished by maintaining the cross-sectional dimensions and increasing the length of a fractional-turn or single-turn solenoidal inductor, as shown in FIG. 5. Thus, in at least one embodiment of the invention, inductors having coils with cross-sections having larger ratios of area enclosed to perimeter are desirable for achieving a particular inductance when the width and height of the core are much greater than the thickness of the conductor from which the coil is formed. For example, a circular core cross-section may have improved performance over square core cross-sections, which have improved performance over rectangular cross-sections. However, when either the width or height of the coil is not much greater than the thickness of the conductor, other effects may become significant and performance may improve by increasing the other dimension although deviating from a circular or square cross-section. Forming an inductor in the traditional metal layers limits the cross-section of the coil forming the inductor, which may limit the resistance of the coil and the Q_{L} of the inductor. In order to increase the cross-sectional area of inductor 800, in at least one embodiment of the invention, at least one of the top turn portions and the bottom turn portions of the inductor 800 are formed in redistribution layers, a package surrounding an integrated circuit, at least one conductor portion on a wafer backside, or any combination thereof.

Redistribution layers may be any layers formed on the integrated circuit used to route electrical connections between contact pads on an IC die and a location of a package contact. This may include depositing and patterning metal layers to transform an existing input/output layout into a pattern that satisfies the requirements of a solder bump design. The redistribution layers are typically formed above a passivation layer, i.e., a layer formed on an integrated circuit to provide electrical stability by protecting the integrated circuit from moisture, contamination particles, and mechanical damage. The passivation layer may include silicon dioxide, silicon nitride, polyimide, or other suitable passivation materials. Redistribution layers are typically formed above integrated circuit bonding pads. These pads, typically coupled to an electronic device formed in the integrated circuit, may include aluminum, copper, titanium, or other suitable material. However, redistribution layers may include additional dielectric and conductive layers formed on an integrated circuit die in the absence of a passivation layer or bonding pads.

Redistribution layers typically have thicknesses substantially greater than the thicknesses of typical dielectric and conductive layers formed on an integrated circuit die. For example, a typical conductive layer in an integrated circuit is less than 1 μm thick and corresponding dielectric layers are also less than 1 μm thick. However, conductive layers in an exemplary redistribution layer are at least 2 μm thick and corresponding dielectric layers are at least 5 μm thick. In another embodiment, the dielectric layers are at least 15 μm thick. Redistribution dielectric layers may include silicon nitride, oxynitride, silicon oxide, benzocyclobutene (BCB), polyimide, or other suitable materials. Redistribution conductive layers may include aluminum, copper, or other suitable materials.

The inductance of a toroidal inductor is approximately

$$\frac{μ {N}^{2} A}{2 π r} ,$$

where A is the cross-sectional area of the coil core, N is the number of turns forming the coil, and r is the toroid radius to the axis (FIG. 7). The inductance approximation is based on the magnetic field at the radius from the axis, but generally, the magnetic field varies within the coil core as a function of the radius from the axis. Techniques described herein may be used to implement inductors of various inductance values and associated quality factors for particular applications (e.g., inductances in the range of approximately 0.9 pH to 275 pH inclusively, having up to twenty turns, and associated quality factors in the range of 8 to 130 inclusively, at frequencies of oscillation in the range of 5 to 10 GHz or greater). Note that for an exemplary oscillator, improvements in Q_{L} by a factor of 2 improve the phase noise by 3 dB and reductions in L by a factor of 2 improve phase noise by 3 dB. In at least one embodiment of the invention, such improvements may be achieved without substantially increasing power consumption of the oscillator circuit, as described above.

The inductance may be varied by varying the number of turns in the inductor coil. For example, referring back to FIG. 8A, inductor 800, designed in traditional integrated circuit layers, has 20 turns in a coil approximately 300 μm long, coil cross-sectional dimensions of approximately 9 μm high and approximately 10 μm wide, an inductance of approximately 275 picoHenries (pH) and an associated Q_{L} of approximately 9 at 10 GHz. In another embodiment, inductor 800 has 20 turns in a coil approximately 1000 μm long, coil cross-sectional dimensions of approximately 9 μm high and approximately 40 μm wide, an inductance of approximately 500 pH, and an associated Q_{L} of 13 at 5 GHz. In at least one embodiment of the invention, at least one turn of the 20 turn inductor is removed to include a capacitor coupled to the inductor. The number of turns removed to insert the capacitor depends upon the size of the capacitor array for a particular application.

Referring to FIG. 9, inductor 900, designed in traditional integrated circuit layers, has an inductance of approximately 128 pH and an associated Q_{L} of approximately 13 at 10 GHz. The coil of inductor 900 has only eight turns is approximately 300 μm long, and has coil cross-sectional dimensions of approximately 9 μm high and 20 μm wide. A portion of an individual turn of inductor 900 includes top turn portion 906, bottom turn portion 908, and sidewall portions 902 and 904. An exemplary current flows through inductor 900 from positive terminal 910 to negative terminal 912, clockwise around the axis orthogonal to the page and intersecting center point 920.

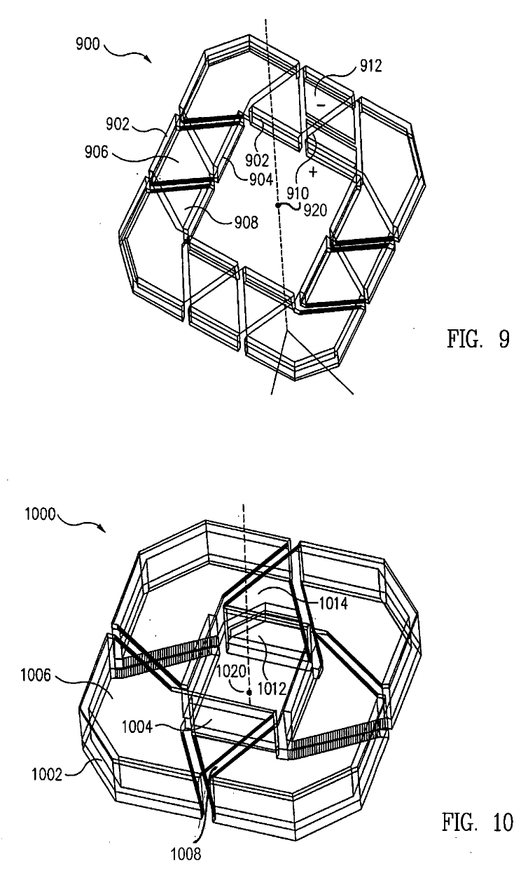

A coil of only four turns, designed in traditional integrated circuit layers, forms inductor 1000 (FIG. 10). When inductor 1000 has coil cross-sectional dimensions of approximately 9 μm high and approximately 20 μm wide, a coil of approximately 200 μm in length and an inductance of approximately 51 pH is achieved with an associated Q_{L} of approximately 11 at 10 GHz. When the coil cross-sectional dimensions are approximately 20 μm high and approximately 20 μm wide, an inductance of approximately 75 pH is achieved with an associated Q_{L} of approximately 14 at 10 GHz. A portion of an individual turn of inductor 1000 includes top turn portion 1006, bottom turn portion 1008, and sidewall portions 1002 and 1004. An exemplary current flows through inductor 1000 from positive terminal 1012 to negative terminal 1014, clockwise around the axis orthogonal to the page and intersecting center point 1020.

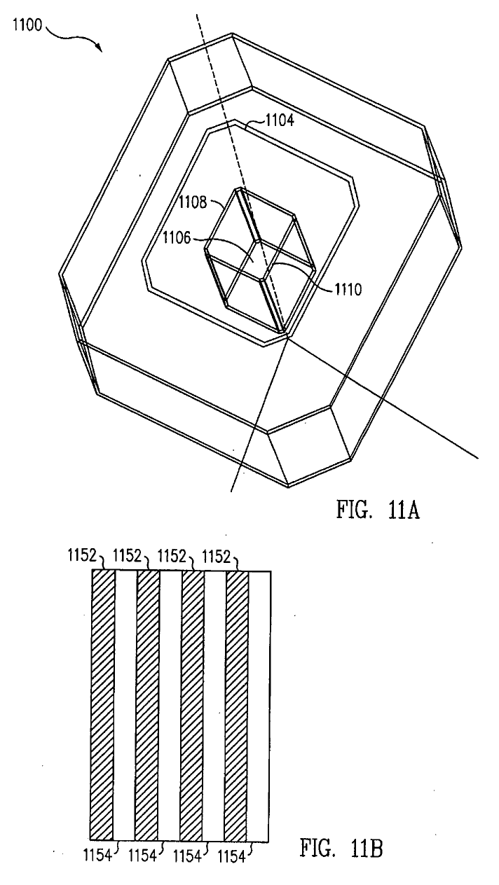

Referring to FIGS. 11-13, in at least one embodiment of the invention, the number of turns is reduced to less than one complete turn. At least one portion of inductor 1100 may be formed in a traditional integrated circuit layer, a redistribution layer, a package surrounding an integrated circuit, a through-substrate via, a conductor portion on a wafer backside, or any combination thereof. In at least one embodiment of the invention, inductor 1100 is designed in traditional integrated circuit layers of an exemplary integrated circuit manufacturing technology. Inductor 1100 has an inductance of approximately 0.9 pH and an associated Q_{L} of approximately 8 at 10 GHz. The coil is approximately 150 μm long and coil cross-sectional dimensions are approximately 9 μm high and 10 μm wide.

In at least one embodiment of the invention, the top conductor portions of inductor 1100 are formed in redistribution layers. Decreases in the center region of the inductor, e.g., region 1106, may increase the cross-sectional area of the coil and the length of the coil. An exemplary inductor 1100 has an inductance of approximately 8 pH and an associated Q_{L} of approximately 56 at 10 GHz. The coil is approximately 750 μm long, coil cross-sectional dimensions are approximately 120 μm wide and 30 μm high, and center region 1106 has a length of approximately 66 μm and a width of approximately 66 μm. In another embodiment, an exemplary inductor 1100 has an inductance of approximately 29 pH and an associated Q_{L} of approximately 133 at 10 GHz. The coil is approximately 750 μm long, cross-sectional dimensions are approximately 120 μm wide and 100 μm high, and center region 1106 has a length of approximately 66 μm and a width of approximately 66 μm.

In at least one embodiment of the invention, the top conductor portions are formed in at least one package layer. An exemplary inductor 1100 has an inductance of approximately 40 pH and an associated Q_{L} of approximately 79 at 10 GHz. The coil is approximately 500 μm long, coil cross-sectional dimensions are approximately 100 μm wide and 100 μm high, and a center region has a length of approximately 26 μm and a width of approximately 26 μm. In another embodiment, an exemplary inductor 1100 has an inductance of approximately 26 pH and an associated Q_{L} of approximately 126 at 10 GHz. The coil is approximately 750 μm long, coil cross-sectional dimensions are approximately 100 μm wide and 100 μm high, and center region 1106 has a length of approximately 66 μm and a width of approximately 66 μm. In at least one embodiment of the invention, the thickness of a bottom conductor portions is increased (e.g., by forming the bottom conductor portions from metal-1 and metal-2, rather than from just metal-1) to improve the Q_{L} at certain frequencies, which also makes the inductor less susceptible to electromagnetic interference penetrating the bottom conductor portion into the core region of the coil.

Preferably, top conductor portions and bottom conductor portions are continuous solid metal portions. However, top and/or bottom conductor portions may be formed from a plurality of conductive lines or slotted top and/or bottom conductor portions. In an exemplary embodiment, conductive lines formed in a first metal layer (e.g., metal lines 1152 of FIG. 11B formed in metal-1) are coupled to and staggered from conductive lines formed in a second metal layer (e.g., metal lines 1154 of FIG. 11B formed in metal-2) forming an individual top or bottom conductor portion.

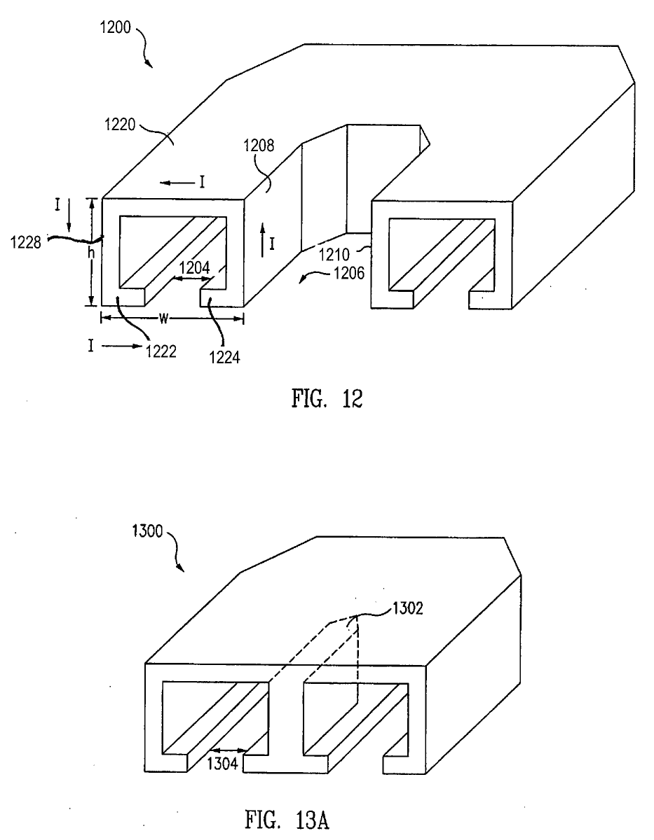

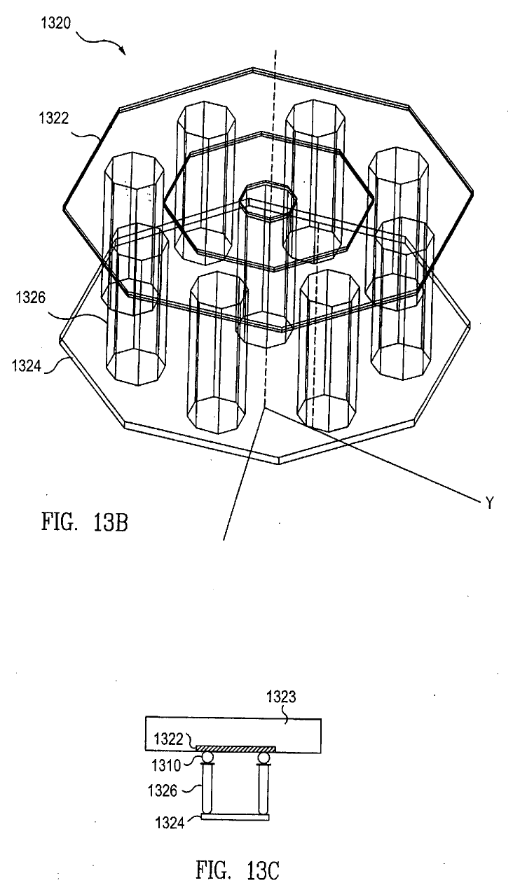

Referring to FIG. 12, a portion of inductor 1200 includes top turn portion 1220, bottom turn portions 1222 and 1224, sidewall portions 1208 and 1228, and center region 1206. An exemplary current flows through inductor 1200 from bottom turn portion 1224 to inner sidewall portion 1208 to top portion 1220 to outer sidewall portion 1228 to bottom turn portion 1222. In at least one embodiment of the invention, the coil of inductor 1200 is formed around an axis such that inner sidewall 1208 and inner sidewall 1210 of inductor 1200 are a negligible distance from the axis and sidewalls 1208 and 1210 form a single inner sidewall structure (e.g., structure 1302 of inductor 1300 in FIG. 13A). Structure 1302 may be a single column of individual vias, a single conductive sheet, or other suitable structure.

Referring to FIGS. 13B and 13C, an exemplary fractional-turn inductor includes turn portions forming an octagonal shape centered around an axis orthogonal to a surface of an integrated circuit. Bottom turn portion 1324 is formed by one or more traditional integrated circuit layers (e.g., metal-8 and metal-9). Sidewalls of inductor 1320 are approximated by columns of vias (e.g., via column 1326). In at least one embodiment of the invention, top turn portion 1322 is formed in at least one redistribution layer. Top turn portion 1322 may be formed in a 3 μm redistribution layer which is spaced 5 μm-15 μm above bottom turn portion 1324. In at least one embodiment of the invention, top turn portion 1322 is formed in a package (e.g., package 1323) and is coupled to via column 1326 by a conductive bump (e.g., conductive bump 1310).

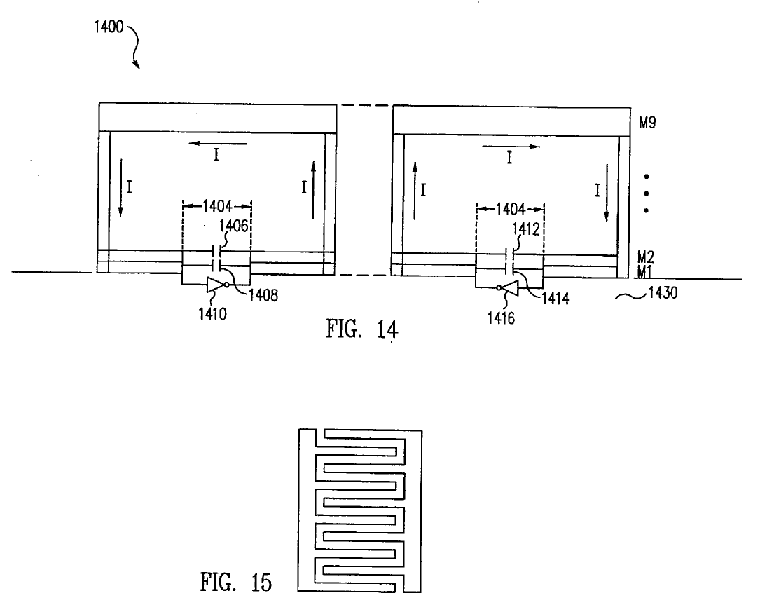

A gap in the conductor portions forming the coil of an exemplary inductor (e.g., gap 1104 of inductor 1100, gap 1204 of inductor 1200, or gap 1304 of inductor 1300) is included for establishing current in the inductor, for example, by coupling the inductor to an associated integrated circuit. Referring to FIG. 14, one or more capacitors (e.g., capacitors 1406, 1408, 1412, and 1414) and one or more amplifiers (e.g., amplifiers 1410 and 1416) are coupled in parallel to inductor 1400 and gap 1404 is provided to accommodate such structures coupled to inductor 1400. In at least one embodiment of the invention the gap has an approximately constant width and is symmetric around the inductor axis (i.e., the axis orthogonal to the surface of the integrated circuit) to facilitate contacts with structures distributed around the inductor axis. Distribution of structures and contacts around the axis reduces restrictions on current flow (e.g., current crowding) between inductor 1100 and the structures coupled to inductor 1100. Capacitors 1408 and 1414 may be transistor capacitors and may be formed in the active area of the integrated circuit along with amplifiers 1410 and 1416.

In at least one embodiment of the invention, capacitors 1406, 1408, 1412, and 1414 are integrated circuit capacitors, i.e., “finger” capacitors (FIG. 15), formed by a plurality of densely-spaced, substantially parallel metal lines, i.e., “fingers.” Alternating ones of the fingers are coupled to form the plates of the capacitor. The bottom conductor portions of inductor 1400 may be formed in both a first conductive layer on the integrated circuit substrate (e.g., metal-1) and at least a second conductive layer on the integrated circuit substrate (e.g., metal-2). Capacitors 1408 and 1414 may be formed in metal-1 and capacitors 1406 and 1412 may be formed in metal-2. However, a capacitor or other integrated circuit element coupled to the inductor may be formed in any combination of conductive layers on the integrated circuit and coupled by conductive vias to any suitable portion of inductor 1400 to provide any suitable current path.

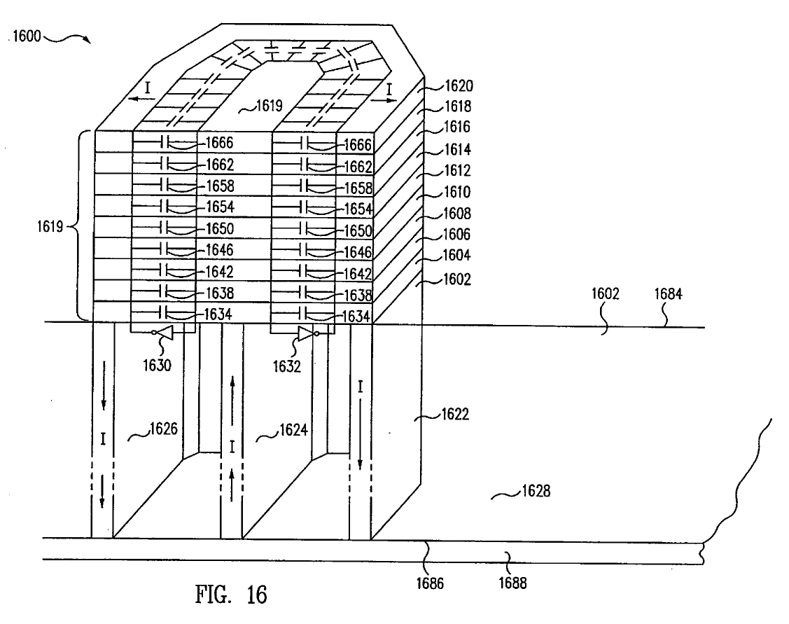

Referring to FIG. 16, in at least one embodiment of the invention, the top turn portions and the bottom turn portions of an inductor (e.g., inductor 1600) are at least partially formed by a conductor portion on a wafer backside to increase the cross-sectional area of an inductor. At least a portion of sidewalls (e.g., sidewalls 1622, 1624, and 1626) of inductor 1600 are formed by through-substrate interconnect. Exemplary through-substrate interconnect is formed in trenches or vias that extend from a frontside of a substrate (e.g, frontside 1684) to a backside of the substrate (e.g., backside 1686). Through-substrate trenches or vias may be formed by KOH etching, deep reactive-ion etching, electrochemical etching, or other suitable technique for forming trenches or vias through a substrate (e.g., a silicon substrate, a silicon-on-insulator substrate, a GaAs substrate, or other substrate suitable for integrated circuit processing). Exemplary through-substrate vias and trenches may be convex (i.e., having a smaller width in the middle of the trench or via than at points closer to the substrate frontside or substrate backside). The height of through-substrate trenches or vias depends upon the substrate thickness and in one exemplary process may have a height in the range including approximately 200 μm and approximately 750 μm for a standard semiconductor substrate.

The through-substrate vias or trenches may be coated with a thin lining of conducting material on the inside surface, may be filled with highly doped polysilicon, may be coated with an insulator liner and filled with a solid conducting core, or may be formed by other suitable techniques and/or materials for forming through-substrate vias or trenches. An insulating liner may be a silicon nitride layer deposited by plasma-enhanced chemical vapor deposition or other suitable technique on the inside surface of the vias or trenches. Silicon nitride may also be formed on the frontside and the backside of the substrate. The conducting material may include copper, silver, gold, aluminum, or other conducting material and may be formed by electroplating a Ta—Ti—Cu seed, or other suitable techniques. Both the seed and the conducting material may be formed on the substrate backside (e.g., conducting material 1688) in addition to being formed within a trench or via. A perforated seed may be formed on the substrate backside, which grows horizontally on the backside to seal the via or trench opening. This technique may be followed by deposits of conducting material from the frontside of the substrate to fill the via or trench. After forming the through-substrate interconnect, the frontside and/or backside of the substrate may be chemical-mechanical polished (i.e., chemical-mechanical planarized). In at least one embodiment of the invention, an additional conducting layer including copper, silver, gold, aluminum, or other suitable conductor may then be formed the backside of the substrate (e.g., conducting layer 1688).

In at least one embodiment of the invention, top turn portions 1619 may be formed in at least one traditional integrated circuit conductive layer (e.g., conductive layers 1604, 1606, . . . 1620, which may correspond to metal-1, metal-2, . . . metal-9 in an exemplary integrated circuit process and are coupled together), at least one redistribution layer, or at least one package layer, or combinations thereof. A gap in top turn portions 1619 is included for coupling inductor 1600 to an associated integrated circuit. For example, inductor 1600 is coupled to amplifiers 1630 and 1632 formed in an active area of the substrate (i.e., active area 1602). In addition, inductor 1600 may be coupled to vertically stacked capacitors 1634, 1638, 1642, . . . 1666, which may be finger capacitors, as described above. Vertically stacked capacitors 1634, 1638, 1642, . . . 1666 may be formed in corresponding integrated circuit conductive layers 1604, 1606, 1608, . . . , 1620. In at least one embodiment of the invention, capacitors 1634, 1638, 1642, . . . 1666 and amplifiers 1634 are distributed around the axis of inductor 1600 (i.e., the axis orthogonal to the surface of the substrate). The top conductor portions may be formed in the same number of conductive layers as the capacitors. However, note that such a technique may reduce the cross-section of the coil, which may be significant to some designs (e.g., inductors formed entirely in the traditional integrated circuit layers). For example, the number of conductive layers used to form the top conductor portions determines the thickness of the top conductor portions and will affect the Q_{L} of the inductor at the particular frequency of oscillation for an oscillator including the inductor.

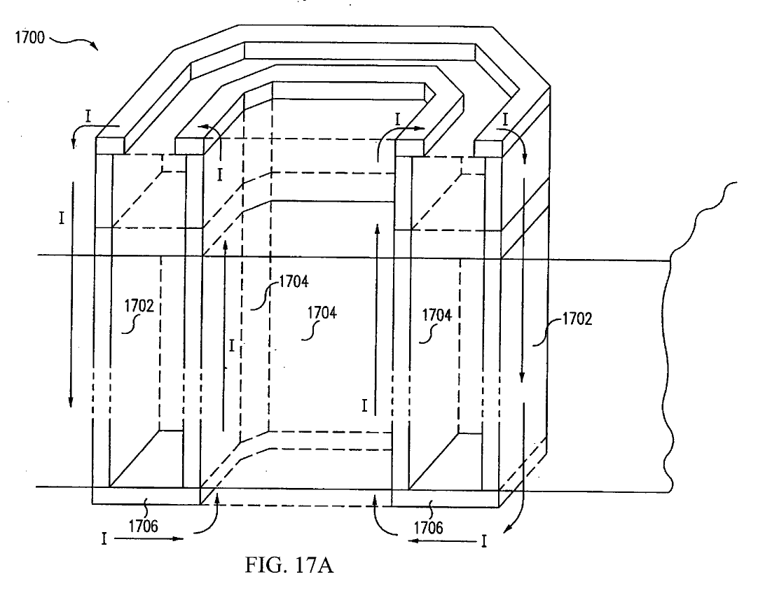

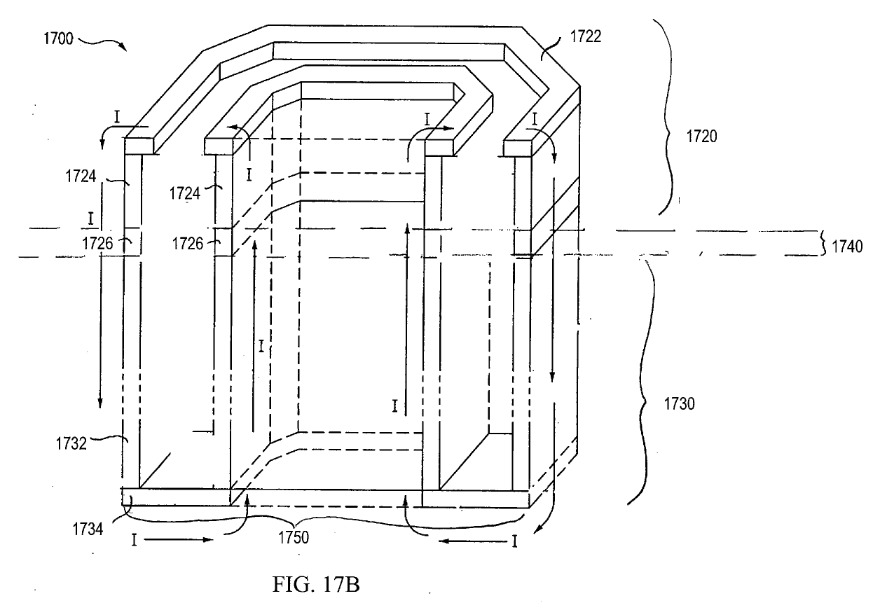

Referring to FIG. 17A, in at least one embodiment of the invention, inner sidewalls of an inductor formed by through-substrate interconnect are formed a substantial distance from the axis of the inductor and form distinct sidewall structures that enclose a substantial center region of the inductor. For example, sidewalls 1704 of inductor 1700 are formed by through-substrate interconnect by techniques described above, and the bottom turn portions of inductor 1700 are formed by backside conductors 1706. Inductors having additional turns may be implemented by through-substrate interconnect techniques and by patterning conductors on the substrate backside to form turns of the inductor.

As described above, the resistance and Q_{L} associated with an inductor may be improved by increasing the cross-sectional area of the coil forming the inductor. In order to increase the cross-sectional area of an inductor (e.g., self-shielding inductor 800, 900, 1000, 1100, 1300, 1320, 1400, 1600, or 1700 in respective ones of FIGS. 8, 9, 10, 11, 13A, 13B, 14, 16, and 17A) the inductor may be formed by conductor portions located in multiple integrated circuit die. Those conductor portions may be formed in individual integrated circuit structures that are attached to each other. For example, referring to FIG. 17B, bottom conductor portion 1734 may be formed in integrated circuit die 1730 and top conductor portion 1722 may be formed in integrated circuit die 1720. At least portions of sidewall conductor portions (e.g., sidewalls formed by conductor portions 1724, 1726, and 1732) may be formed by interconnect structures (e.g., sidewall conductor portion 1726 formed in region 1740) between the first and second integrated circuit die. Note that although sidewall portions 1732 are shown as being formed in a first integrated circuit die, sidewall portions 1724 are shown as being formed in a second integrated circuit die, and sidewall portions 1726 are shown as being formed in interconnect structures between the first and second integrated circuit die, sidewall portions of an inductor may be formed in various combinations of the first integrated circuit die, the second integrated circuit die, additional integrated circuit die between the first and second integrated circuit die, and interconnect between these integrated circuit die. Three-dimensional packaging techniques may be used to package multiple integrated circuit structures and to couple relevant portions of the multiple integrated circuit die to form the inductor.

Exemplary three-dimensional packaging techniques include wafer thinning (e.g., thinning of wafers to thicknesses as thin as an active layer, e.g., below 50 μm), wafer-to-wafer bonding, die-to-wafer bonding, wafer-through-hole technologies, around-the-edge interconnect, forming bump layers on multiple faces of a die, and folded multiple-die packaging (e.g, applying adhesive film to top surfaces of die and folding over extended area followed by curing and inclusion of solder balls). A base die may be flip-chip attached or wirebond attached, and stacked die are typically wirebond attached. Stacked die may be bonded directly to a substrate or down to a host site. Three-dimensional design automation tools may be used to analyze electrical, mechanical and thermal effects of stacked integrated circuits.

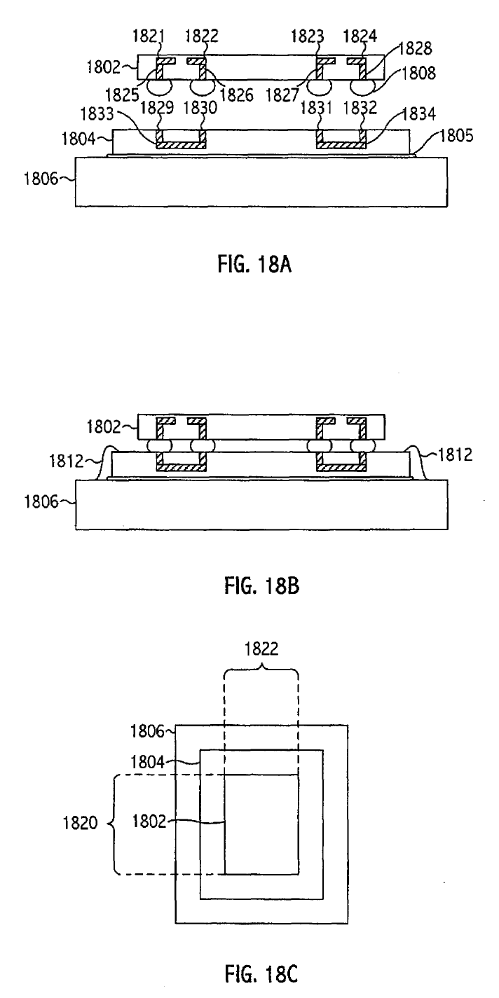

Referring to FIGS. 18A-18C, in at least one embodiment of an inductor, portions of the inductor are formed on a first integrated circuit die (e.g., integrated circuit die 1804) and portions of the inductor are formed on a second integrated circuit die (e.g., integrated circuit die 1802). Integrated circuit die 1804 may be attached to package substrate 1806 by an adhesive film or tape (e.g., adhesive layer 1805), or other suitable technique. Package substrate 1806 may be glass, plastic, FR-4, ceramic, or other suitable material. Conductive bumps 1808, which add additional vertical dimension (e.g., 100 μm in at least one technology) to the inductor, are formed on integrated circuit die 1802 forming sidewall portions of the inductor. Integrated circuit die 1802 is flipped and attached to integrated circuit die 1804 by an appropriate interconnect technique. At least one of the integrated circuit die may have at least one dimension (e.g., x-dimension 1822 or y-dimension 1820 of integrated circuit die 1802) that is as small as a dimension of the inductor (e.g. x-dimension 1750 of FIG. 17B). Integrated circuit die 1804 is wirebonded to package substrate 1806 (e.g., by bondwires 1812). Alternatively, integrated circuit die 1802 and integrated circuit die 1804 may be packaged in a lead frame package.

Integrated circuit die 1802 includes top turn portions (e.g., conductor portions 1821, 1822, 1823, and 1824) and sidewall turn portions (e.g., conductor portions 1825, 1826, 1827, and 1828), which are formed in traditional integrated circuit layers (e.g., any suitable combination of conductive layers metal-1 through metal-9). Similarly, integrated circuit die 1804 includes bottom turn portions (e.g., conductor portions 1833 and 1834) and sidewall turn portions (e.g., conductor portions 1829, 1830, 1831, and 1832), which are formed in traditional integrated circuit layers (e.g., any suitable combination of conductive layers metal-1 through metal-9). Although both integrated circuit die 1802 and 1804 are shown including sidewall turn portions, integrated circuit die 1802 may include only top turn portions and/or integrated circuit die 1804 may include only bottom turn portions.

The vertical dimension of the sidewall turn portions coupled with the top turn portions will vary according to integrated circuit manufacturing technology. In an exemplary integrated circuit manufacturing technology, integrated circuit 1802 may include conductor portions having a vertical dimension ranging from approximately 1 μm to approximately 9 μm, depending upon the number of conductive layers used and whether integrated circuit 1802 includes sidewall turn portions in addition to top turn portions. Similarly, integrated circuit 1804 may include conductor portions having a vertical dimension ranging from approximately 1 μm to approximately 9 μm, depending upon the number of conductive layers used and whether integrated circuit 1804 includes sidewall turn portions in addition to bottom turn portions. Individual ones of conductive bumps 1808 couple conductor portions 1825, 1826, 1827, and 1828 to respective ones of conductor portions 1829, 1830, 1831, and 1832. In embodiments of the inductor that do not include sidewall portions on one or both of integrated circuit die 1802 and 1804, conductive bumps 1808 are coupled to top turn portions and/or bottom turn portions of integrated circuit die 1802 and 1804, respectively.

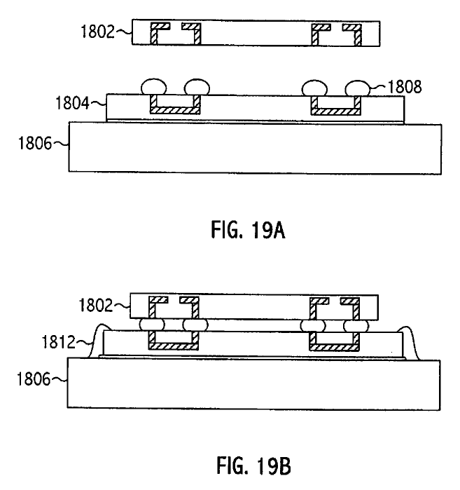

In another technique for forming an inductor (see FIGS. 19A and 19B), integrated circuit die 1804 is attached to package substrate 1806. Conductive bumps 1808 are formed on integrated circuit die 1804 and integrated circuit die 1802 (which does not include conductive bumps) is attached to integrated circuit die 1804 by an appropriate interconnect technique. Integrated circuit die 1804 is then wirebonded to package substrate 1806 (e.g., by bondwires 1812).

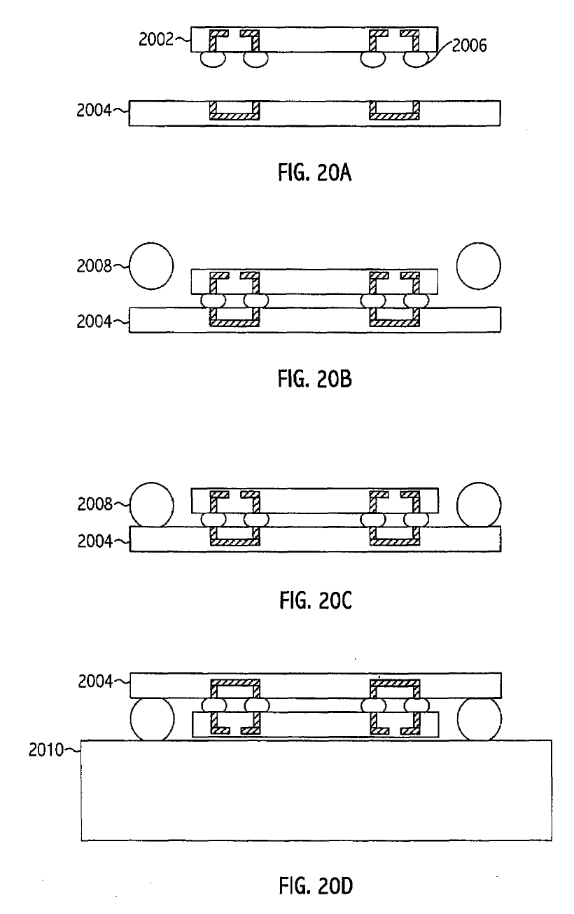

Referring to FIGS. 20A-20D, in another technique for forming an inductor, conductive bumps 2006 are formed on integrated circuit die 2002. Integrated circuit die 2002 is then joined to integrated circuit die 2004 by a suitable technique. Solder balls 2008 are then loaded onto integrated circuit die 2004. Integrated circuit die 2004, which is attached to integrated circuit die 2002, is then flipped and joined to package substrate 2010 by a suitable technique.

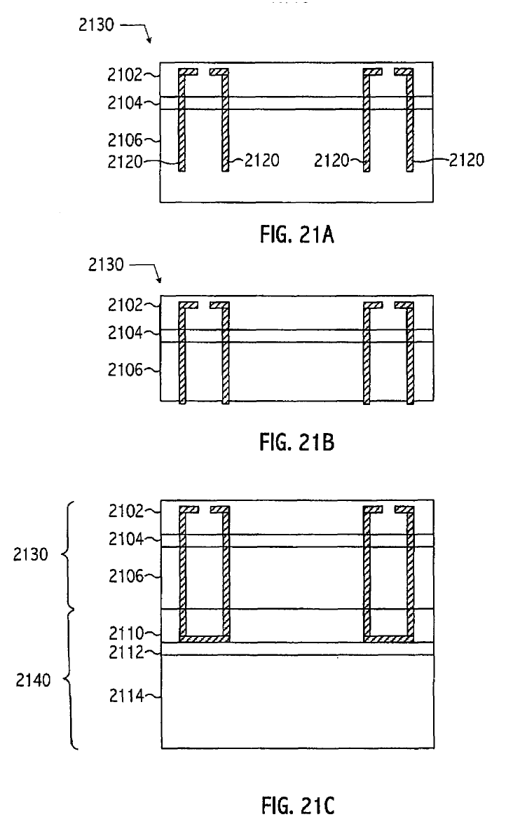

In at least one embodiment of the invention, multiple integrated circuit die are stacked by a technique illustrated in FIGS. 21A-C. Conductive vias (e.g., Cu vias 2120) are formed in the substrate (e.g., substrate 2106) of an integrated circuit die after front-end-of-line (e.g., formation of transistors in active layers 2104) and contact processing, prior to formation of back-end-of-line metallization layers (e.g., metallization layers 2102). The conductive vias are filled with a conductive plug. After back-end-of-line processing, the substrate may be thinned to expose the conductive plugs (FIG. 21B) and bonded to another integrated circuit die during a die-to-wafer bonding process, e.g., by directly bonding one conductor to another conductor by thermo-compression technology (FIG. 21C). For example, substrate 2106 of integrated circuit die 2130 is bonded to metallization layers 2110 of integrated circuit die 2140. This technique may be repeated to obtain multiple die stacks. Such a technique may be used with ultra-thin-chip-stacking technology, which stacks thin dies on active device wafers and are interconnected with the host wafer using a multi-layer, thin-film technology and which allows stacking dies with varying dimensions.

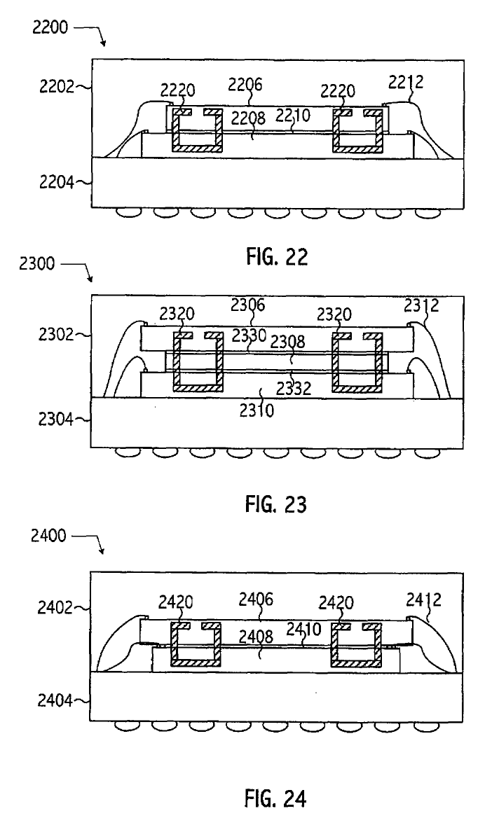

Referring to FIGS. 22-24, conductor portions of an inductor are formed in multiple integrated circuit die (e.g., integrated circuit die 2206 and 2208, integrated circuit die 2306, 2308, and 2310, and integrated circuit die 2406 and 2408) included in a package of a packaged integrated circuit structure (e.g., packaged integrated circuit structure 2200, packaged integrated circuit structure 2300, and packaged integrated circuit structure 2400, respectively). The multiple integrated circuit die may be configured in a pyramid stack configuration (i.e., smaller die are placed on top of larger die, e.g., configuration of packaged integrated circuit structure 2200), a same-die stack configuration (i.e., same size die with a silicon spacer placed between the two die, e.g., configuration of packaged integrated circuit structure 2300), an overhang cross-stack configuration (i.e., rectangular die are placed at 90 degrees on top of each other, e.g., configuration of packaged integrated circuit structure 2400), or other suitable die configuration. The conductor portions in the stacked integrated circuit die are coupled to each other by any suitable interconnect technique, e.g., through-substrate interconnect and/or redistribution layer connections. The vertical dimension of a self-shielding inductor may be increased further by including additional integrated circuit die. For example, packaged integrated circuit structure 2300 includes spacer die 2308 and includes through-substrate vias to couple turn portions in die 2306 to turn portions in die 2310. In at least one embodiment of the invention, an adhesive tape (e.g., adhesive layer 2210, 2330, 2332, or 2410) is patterned to allow connection points between a first die and a second die to form a multi-die inductor.

In an exemplary multi-die inductor structure, a first integrated circuit die includes a phase-locked loop and an oscillator circuit including portions of an inductor for a clock and data recovery application. At least a second integrated circuit die includes additional portions of the inductor and may also include any combination of memory circuits, sensor circuits, additional logic circuits, and inductor shielding structures (e.g., Faraday cage). Individual ones of the multiple die of the exemplary integrated circuit structure may be implemented in the same integrated circuit manufacturing technology (e.g., Si-CMOS, GaAs, or other suitable integrated circuit manufacturing technology) or different processing technologies. For example, one integrated circuit die may include a substrate compatible with Si-CMOS processing (e.g., silicon substrate or glass substrate) and another integrated circuit die is a GaAs integrated circuit substrate, a plastic substrate with conductive traces, or other substrate material that is incompatible with Si-CMOS processing.

While circuits and physical structures are generally presumed, it is well recognized that in modern semiconductor design and fabrication, physical structures and circuits may be embodied in computer readable descriptive form suitable for use in subsequent design, test, or fabrication stages. Structures and functionality presented as discrete components in the exemplary configurations may be implemented as a combined structure or component. The invention is contemplated to include circuits, systems of circuits, related methods, and computer-readable medium encodings of such circuits, systems, and methods, all as described herein, and as defined in the appended claims. As used herein, a computer readable medium includes at least disk, tape, or other magnetic, optical, semiconductor (e.g., flash memory cards, ROM), or electronic medium and a network, wireline, wireless or other communications medium.

The description of the invention set forth herein is illustrative, and is not intended to limit the scope of the invention as set forth in the following claims. For example, while the invention has been described in at least one embodiment in which the inductor is self-shielding, one of skill in the art will appreciate that the teachings herein can be utilized for other inductor structures. In addition, although the invention has been described in at least one embodiment in which the inductor is included in an oscillator circuit, one of skill in the art will appreciate that the teachings herein can be utilized for other circuits that include inductor structures (e.g., LC filter circuits). Variations and modifications of the embodiments disclosed herein, may be made based on the description set forth herein, without departing from the scope and spirit of the invention as set forth in the following claims.

What is claimed is:

1. An apparatus comprising an inductor formed partially in a first integrated circuit die and formed partially in at least a second integrated circuit die.

2. The apparatus, as recited in claim 1, wherein the inductor is formed partially in at least one interconnect structure between the first integrated circuit die and the second integrated circuit die.

3. The apparatus, as recited in claim 2, wherein the interconnect structure includes one or more conductive bumps.

4. The apparatus, as recited in claim 1, wherein the inductor is formed partially in multiple conductive layers on the first integrated circuit die and partially in multiple conductive layers on the second integrated circuit die.

5. The apparatus, as recited in claim 1, wherein the inductor is self-shielding and configured to generate a magnetic field in response to a current flowing through coupled conductor portions of the self-shielding inductor, the magnetic field being substantially confined to a core region of the self-shielding inductor.

6. The apparatus, as recited in claim 1, wherein the inductor includes a coil of coupled conductor portions, the coil being formed around an axis and the coupled conductor portions substantially enclosing a core region within the coil, the axis being coplanar with cross-sections of the coil and the axis being external to cross-sections of the coil.

7. The apparatus, as recited in claim 1, wherein the inductor is formed by at least a fractional number of turns and at least a bottom turn portion is formed in the first integrated circuit die and at least a top turn portion is formed in the second integrated circuit die.

8. The apparatus, as recited in claim 6, wherein the coil forms a perimeter of a substantially symmetric polygonal center of the self-shielding inductor.

9. The apparatus, as recited in claim 6, wherein the coil comprises:
first, second, third, and fourth portions,
wherein the first portion of the coil is parallel to the second portion of the coil, the first and second portions of the coil being approximately equidistant from the axis, and the first and second portions of the coil being coupled to conduct substantially equal currents in substantially opposite directions, and
wherein the third portion of the coil is parallel to the fourth portion of the coil, the third and fourth portions of the coil being approximately equidistant from the axis, and the third and fourth portions of the coil being coupled to conduct substantially equal currents in substantially opposite directions.

10. The apparatus, as recited in claim 6, wherein substantially equal and substantially opposite magnetic fields are generated parallel to a first plane intersecting the axis in corresponding portions of the core region in response to a current flowing through corresponding coupled conductor portions and substantially equal and substantially opposite magnetic fields are generated parallel to at least a second plane intersecting the axis in corresponding portions of the core region in response to a current flowing through corresponding coupled conductor portions.

11. The apparatus, as recited in claim 1, wherein the second integrated circuit die includes conductive traces on a plastic substrate.

12. The apparatus, as recited in claim 6, wherein a number of turns forming the coil is in a range from one turn to approximately twenty turns, inclusively.

13. The apparatus, as recited in claim 6, wherein less than approximately one complete turn forms the coil.

14. A method of manufacturing comprising:
interconnecting a first integrated circuit die and at least a second integrated circuit die to form an inductor, the first integrated circuit die including first conductor portions of the inductor and the second integrated circuit die including second conductor portions of the inductor.

15. The method, as recited in claim 14, wherein the interconnecting forms electrical connections between the first conductor portions and the second conductor portions.

16. The method, as recited in claim 14, wherein the interconnecting includes forming conductive bumps on at least one of the first integrated circuit die and the second integrated circuit die.

17. The method, as recited in claim 14, wherein the interconnecting includes forming through-substrate interconnect for coupling the first conductor portions to the second conductor portions.

18. The method, as recited in claim 14, wherein the inductor is self-shielding and configured to generate a magnetic field in response to a current flowing through coupled conductor portions, the magnetic field being substantially confined to a core region of the self-shielding inductor.

19. An inductor comprising:
a first portion in a first integrated circuit die;
at least a second portion in a second integrated circuit die; and
means for interconnecting the first portion and the second portion.

20. The inductor, as recited in claim 19, wherein inductor generates a magnetic field in response to a current flowing between a first node and a second node, the magnetic field being substantially confined to a substantially enclosed region of the inductor.

21. The apparatus, as recited in claim 19, further comprising:
means for packaging at least the first integrated circuit, the second integrated circuit and the means for interconnecting.
